(19) United States
(12) Patent Application Publication
(10) Pub. No.: US 2015/0108287 A1
(43) Pub. Date: Apr. 23, 2015

(54) WIRE HOLDER MOUNTING STRUCTURE AND DISPLAY DEVICE

(71) Applicants: Shinichi Arai, Osaka-shi (JP); Toshihiro Yamamichi, Osaka-shi (JP); Yutaka Yoshizawa, Osaka-shi (JP)

(72) Inventors: Shinichi Arai, Osaka-shi (JP); Toshihiro Yamamichi, Osaka-shi (JP); Yutaka Yoshizawa, Osaka-shi (JP)

(73) Assignee: SHARP KABUSHIKI KAISHA, Osaka-shi, Osaka (JP)

(21) Appl. No.: 14/383,813

(22) PCT Filed: Aug. 20, 2012
(86) PCT No.: PCT/JP2012/070963

§ 371 Date: Sep. 8, 2014

(30) Foreign Application Priority Data
Mar. 9, 2012 (JP) 2012-052825
Aug. 7, 2012 (JP) 2012-174736

(51) Int. Cl. H05K 5/02

(52) U.S. Cl. CPC H05K 5/0204
USPC 248/65

(57) ABSTRACT

Provided is a technology which makes an undercut portion small and reduces a limit on a mold structure in a wire holder mounting structure. A holder fixing portion (30) formed in a cabinet (20) is configured by including a box portion (32) and a holding rib (40). The box portion (32) has an open in an upper side in drawings, and is configured by right and left wall surfaces (32a), a rear wall surface (32b) and a bottom surface (32c). A holder mounting hole (34) is formed in the rear wall surface (32b), and a wire holder (90) is inserted in a direction of the holder mounting hole (34) (direction of an arrow X1 in the drawings) to be fixed. In the fixed state, a leaf spring portion (92) (holding portion) of the wire holder (90) is placed so as to be in contact with the holding rib (40).

### TECHNICAL FIELD

The present invention relates to a wire holder mounting structure and a display device, and relates to, for example, a wire holder mounting structure formed in a housing and a display device provided with such a wire holder mounting structure.

### BACKGROUND ART

In a liquid crystal television, a wire holder (hereinafter, referred to as “WH”) is used in a manner fixed to a cabinet in order to hold a harness of a speaker or the like, in some cases. Though there are various methods for fixing a WH, a snap-type (push mount) fixing method is used in view of workability and the like, in many cases.

Then, various technologies for properly holding a harness in a case where the snap-type fixing method is used have been proposed. For example, there is a clip for fixing a wire harness which makes it difficult that the wire harness comes off even when being applied with external force (refer to PATENT LITERATURE 1, for example). Specifically, in the clip for fixing a wire harness provided with a substrate which is put along the wire harness and a locking leg portion which is protruded from one surface side of the substrate and attached to a fixing body side, the clip for fixing a wire harness has an inserting and locking portion, which is inserted into and locked in the wire harness, protruded from a surface of the substrate on the opposite side of a surface from which the locking leg portion is protruded.

### CITATION LIST

### Patent Literature

PATENT LITERATURE 1: Japanese Laid-Open Patent Publication No. 1998-309023

### SUMMARY OF INVENTION

### Technical Problem

Meanwhile, in order to form a cabinet structure for fixing a WH, a shape of undercut is necessary, and in order to create the undercut, a mold which uses an inclined core is to be necessary. The inclined core requires a limit on a structure and a shape of the mold, and is therefore desired to be as small as possible.

The present invention has been made in view of the above situation, and an object thereof is to provide a technology solving the above problem.

### Solution to Problem

A wire holder mounting structure of the present invention includes a holder fixing portion which is integrally formed on a cabinet and which has a mounting hole by which a wire holder of a snap fixing type is able to be attached and a rib which is formed so as to extend from the holder fixing portion, in which an inner side of a surface, on which the mounting hole is formed, of the holder fixing portion is an undercut portion.

A display device of the present invention includes the above-described wire holder mounting structure, in which the wire holder holding a harness is fixed to the wire holder mounting structure as well as a holding portion of the wire holder is in contact with the rib in a fixed state.

### Advantageous Effects of Invention

According to the present invention, in the wire holder mounting structure, it is possible to make an undercut portion small and reduce a limit on a mold structure.

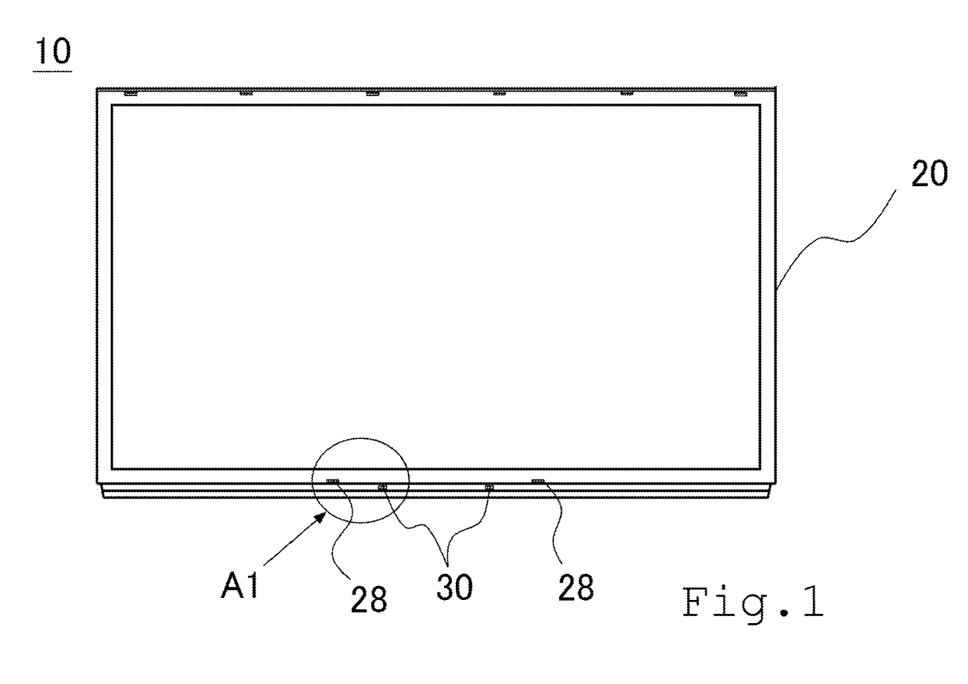

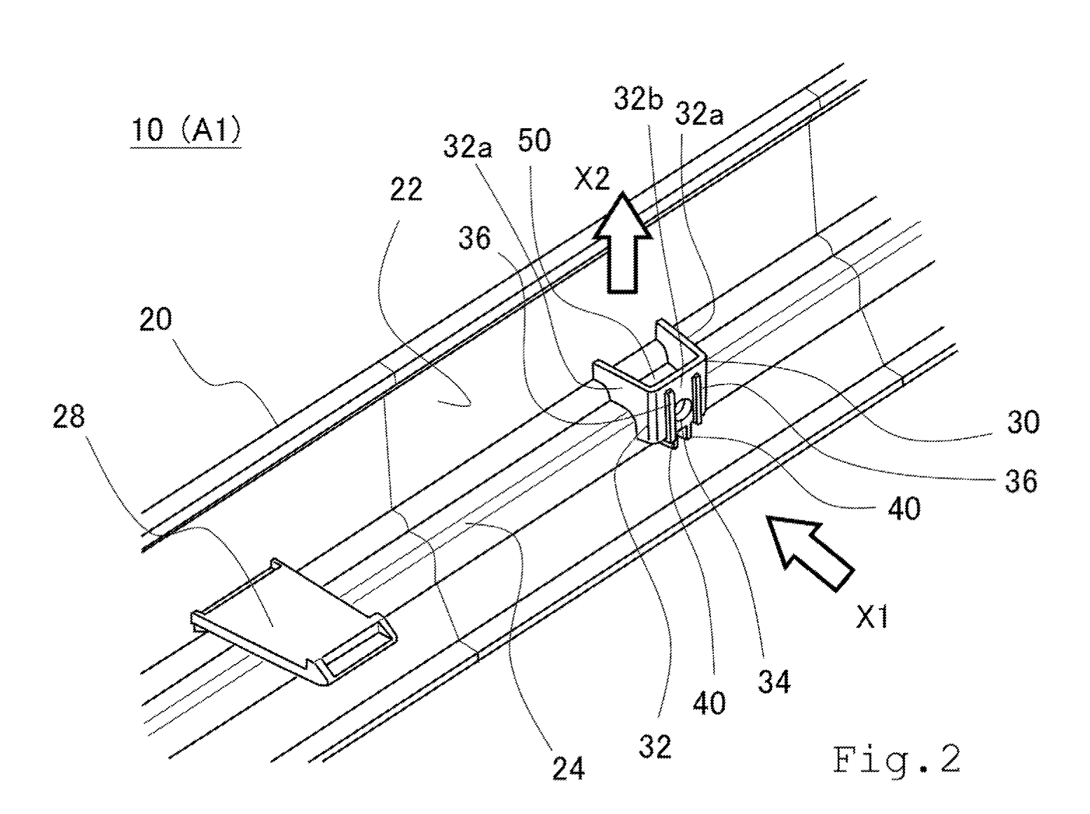

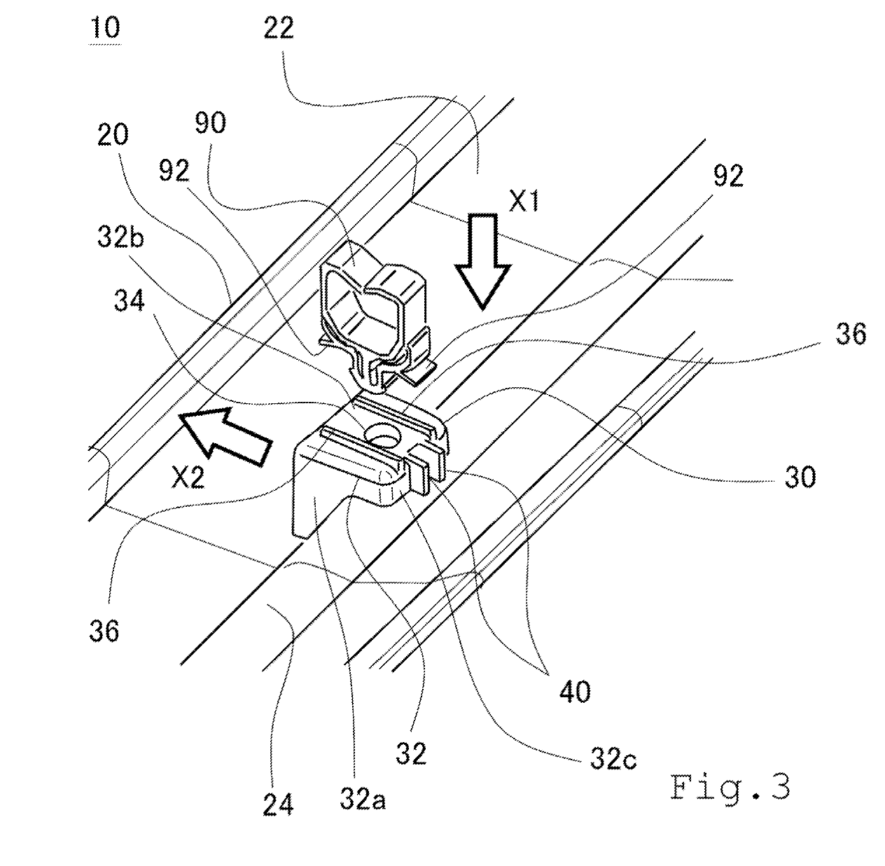

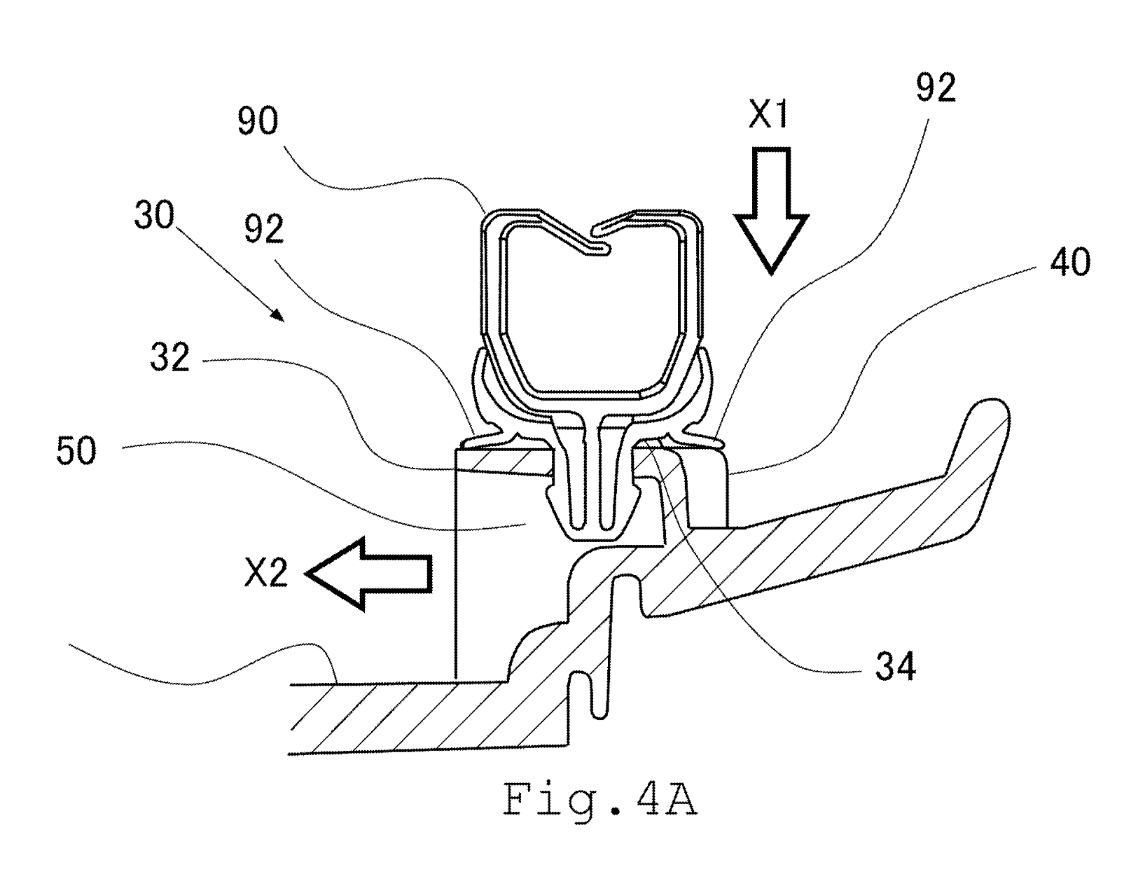

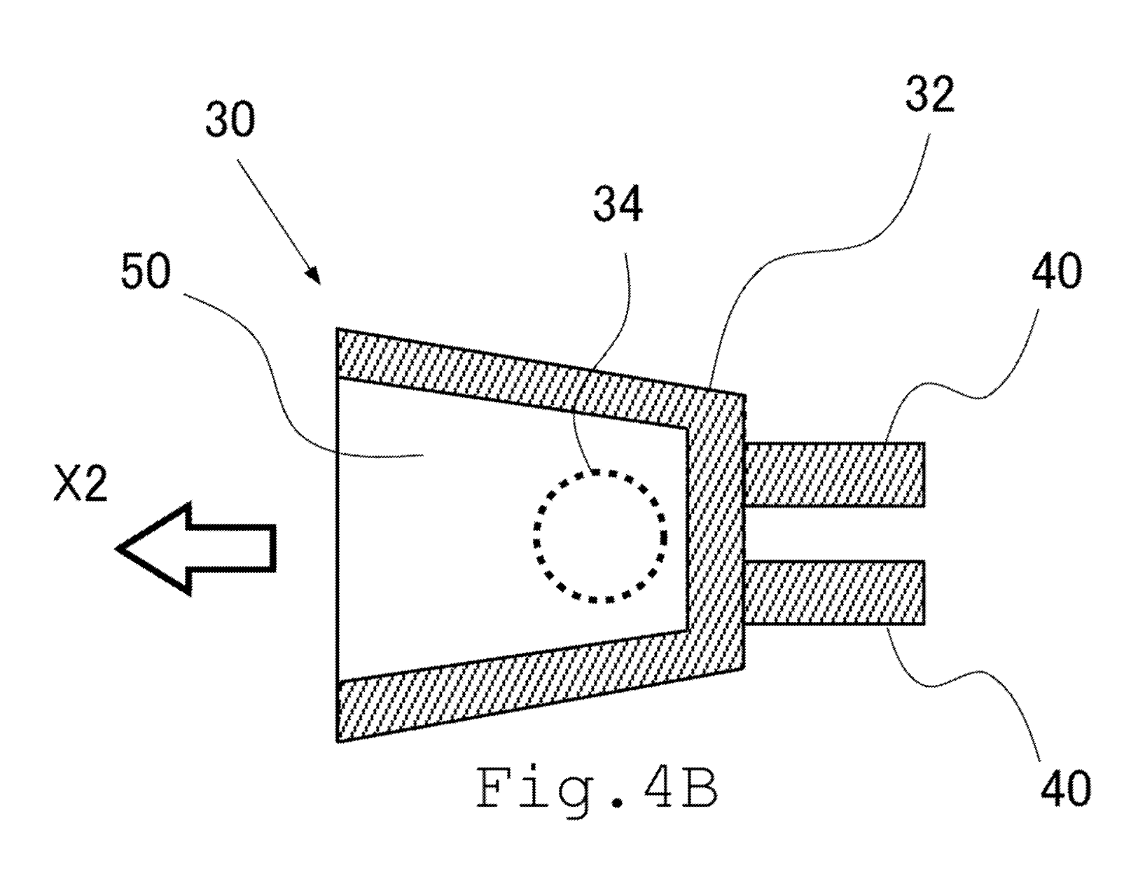

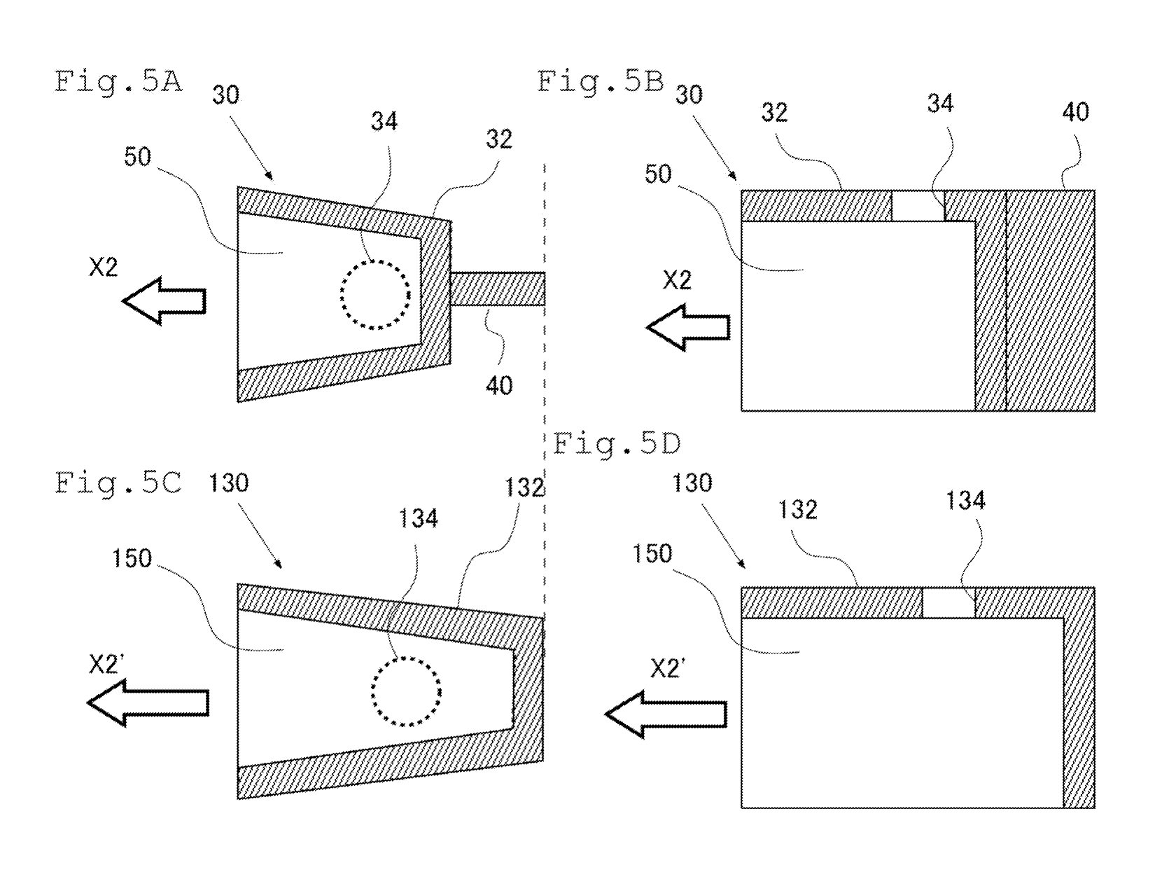

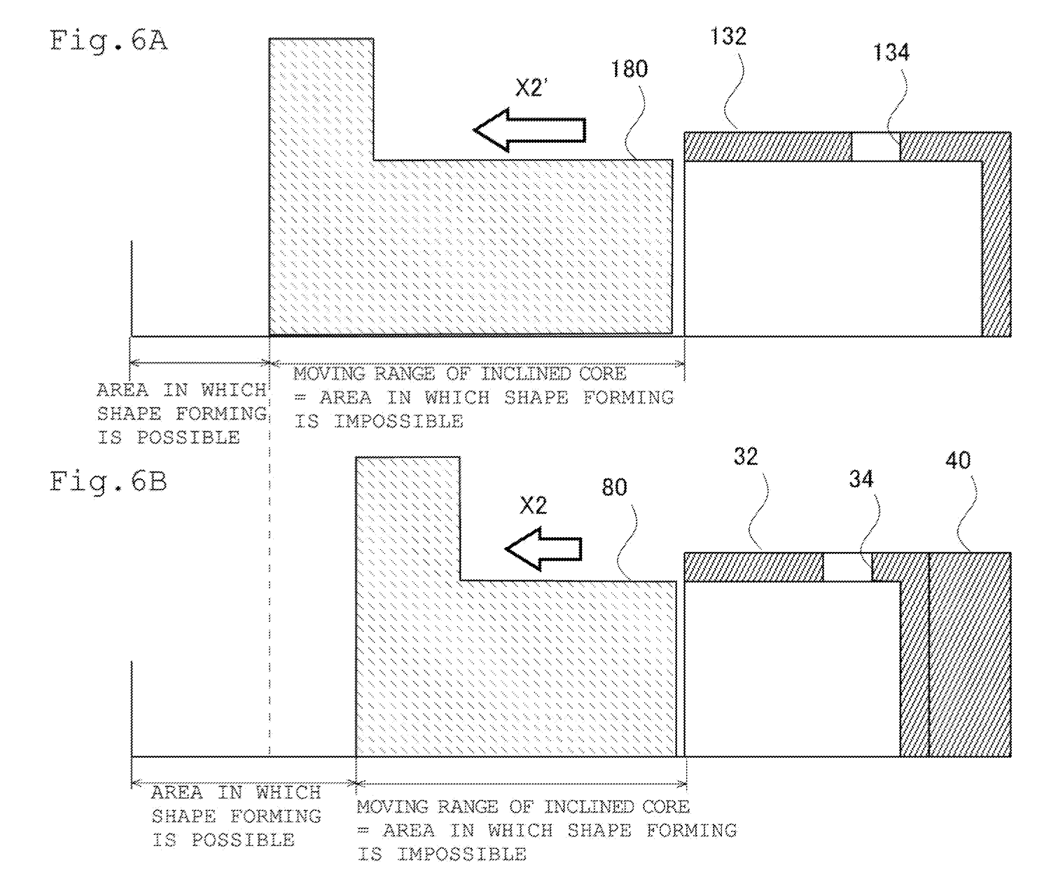

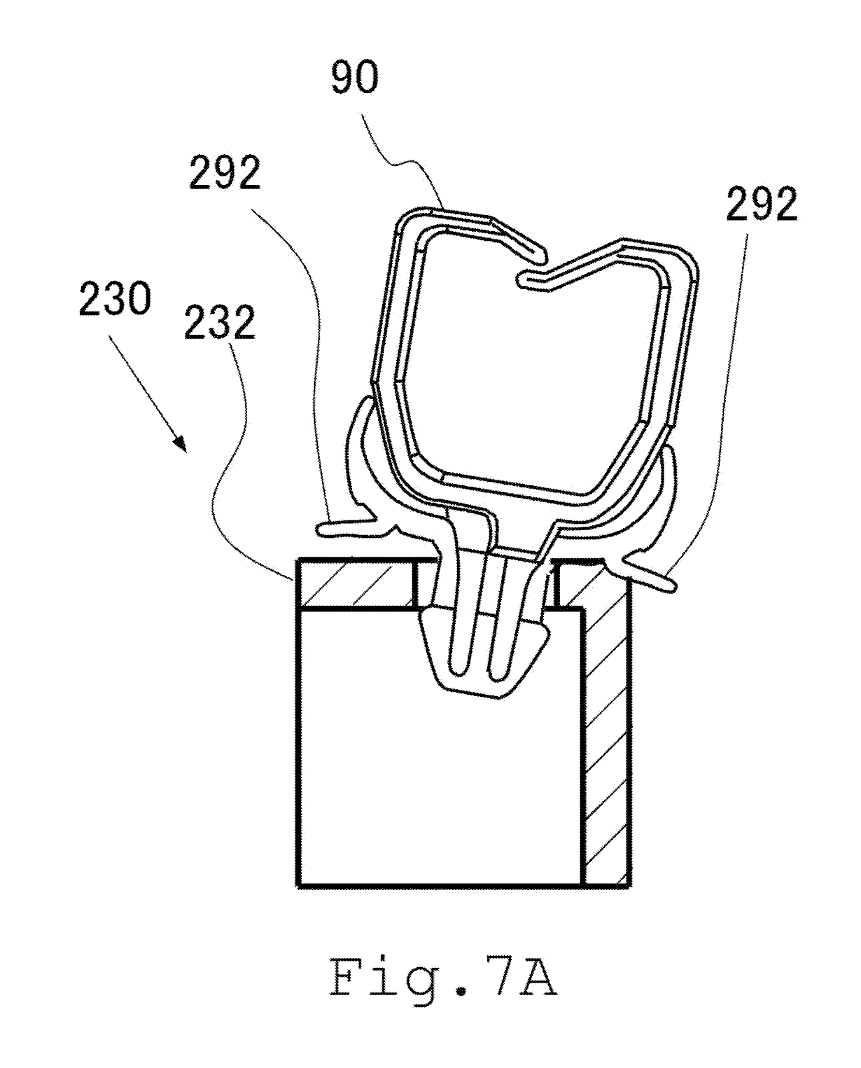

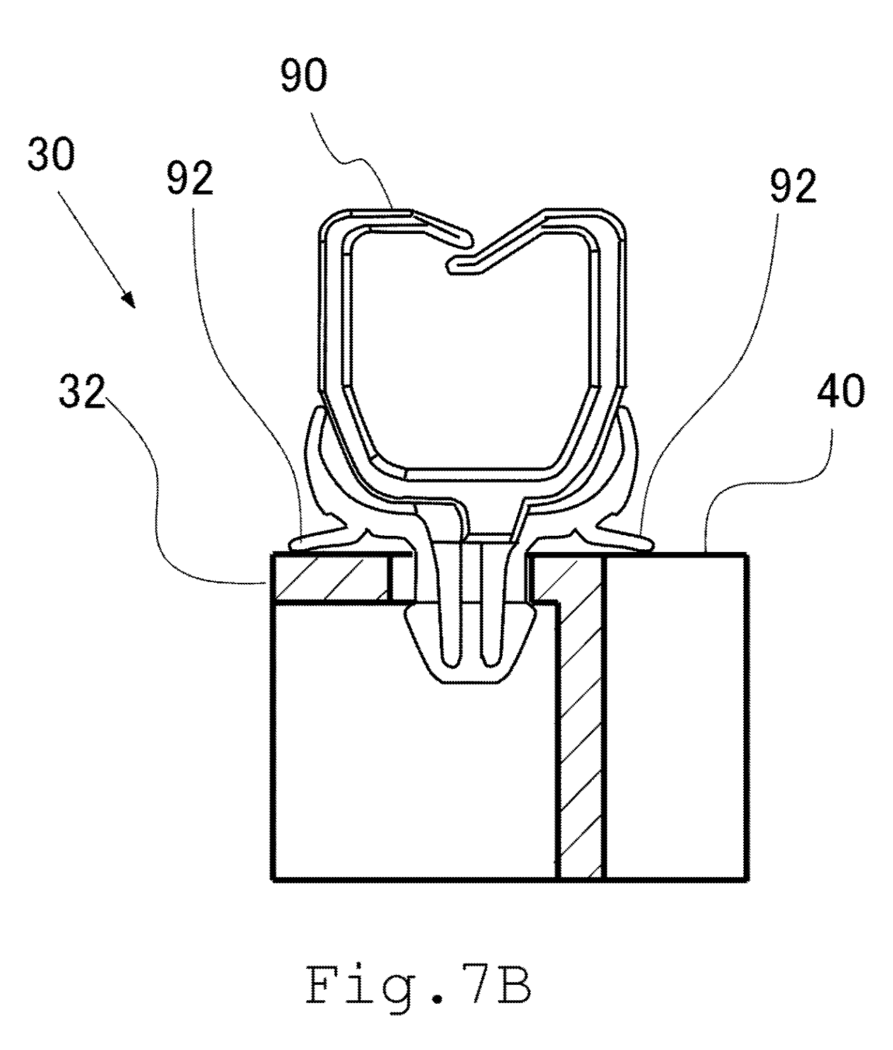

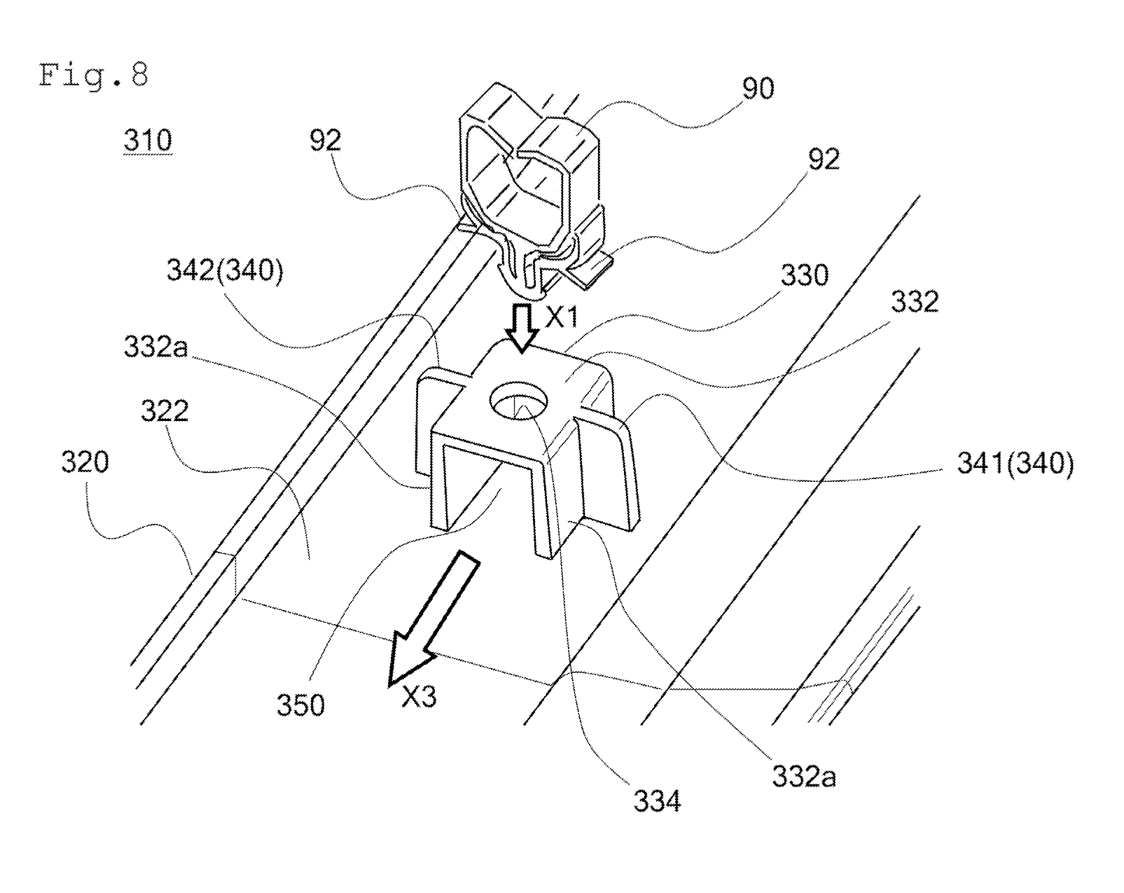

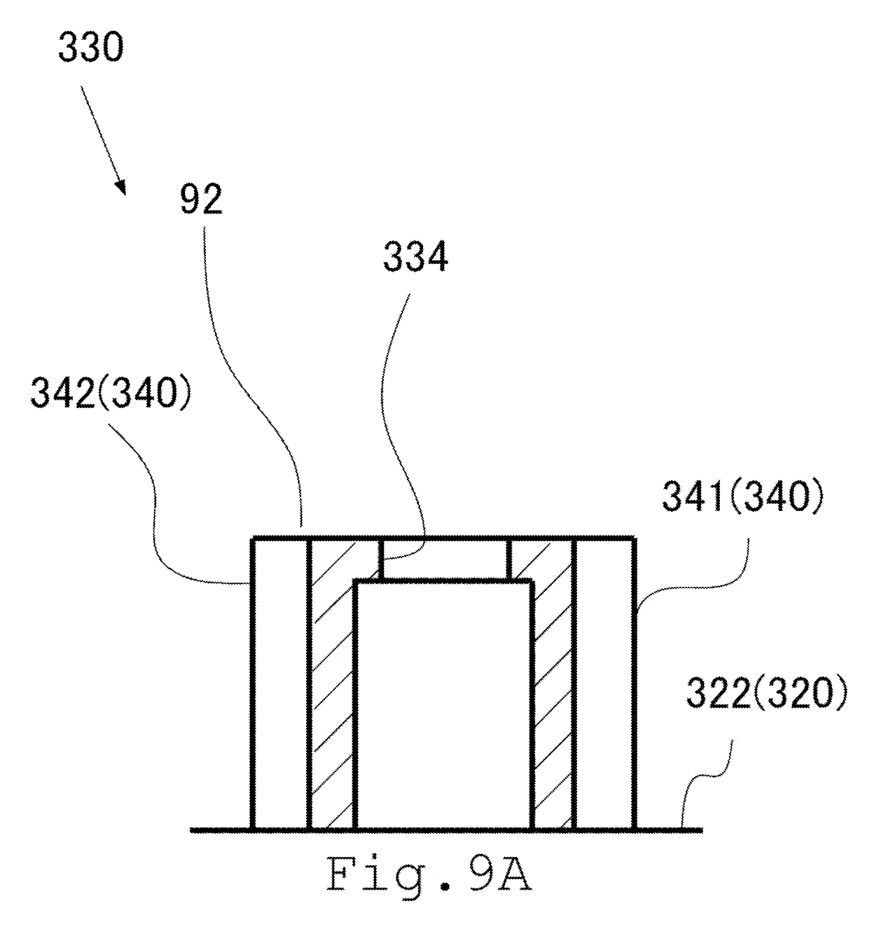

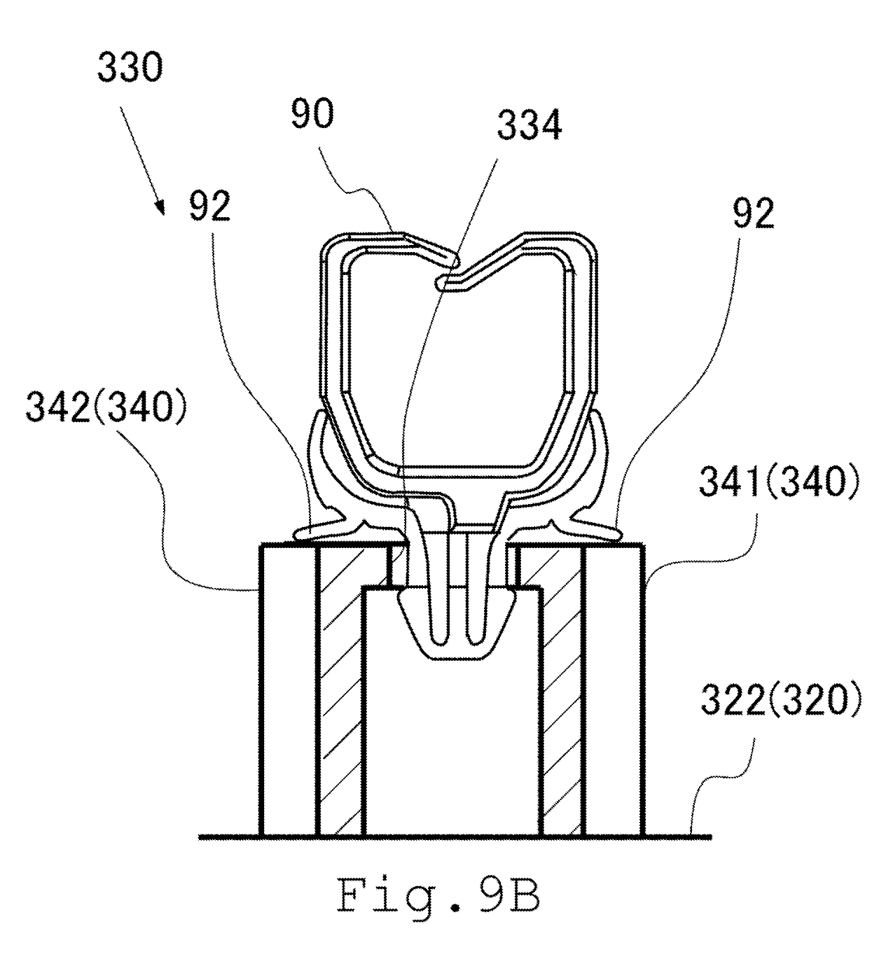

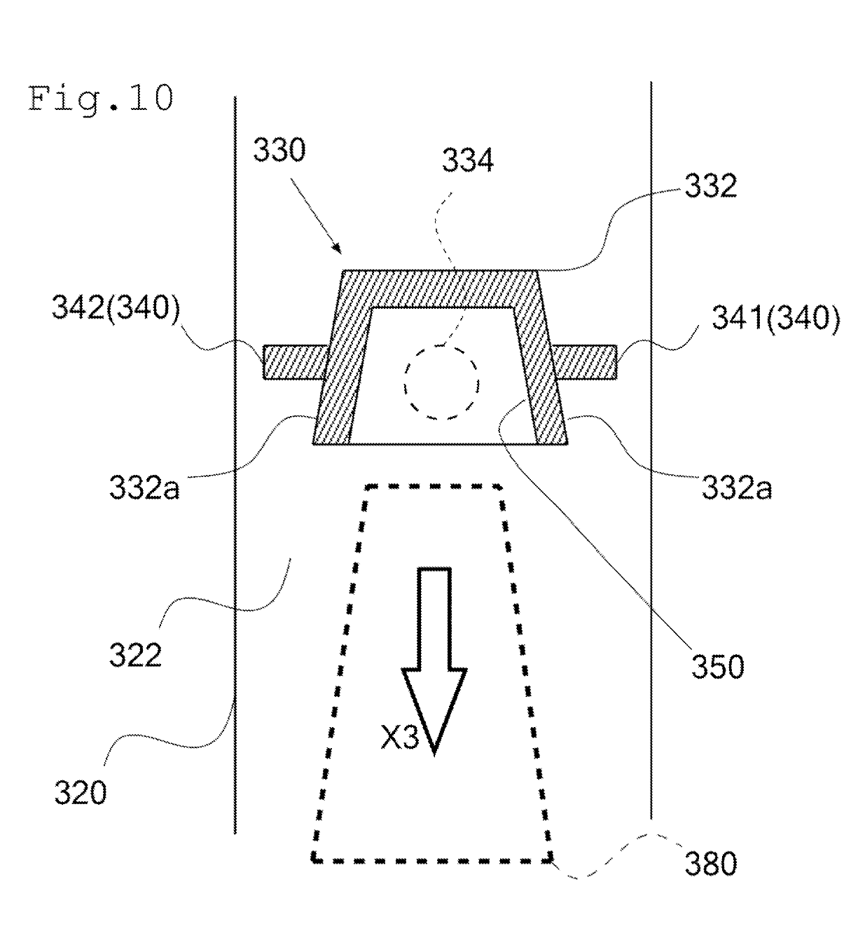

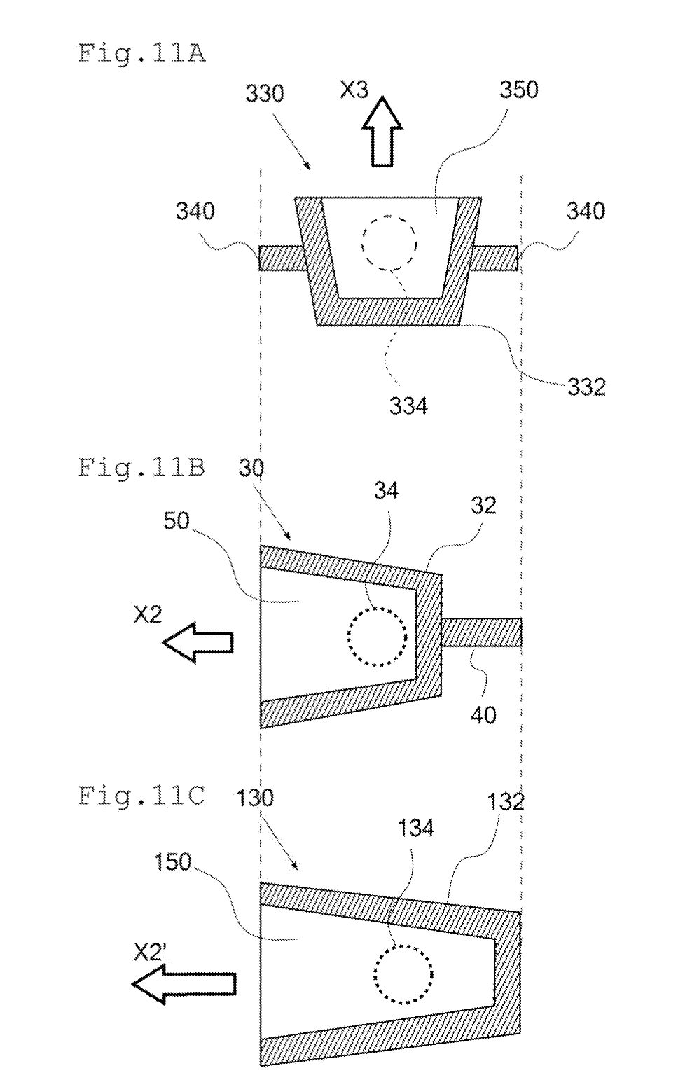

### BRIEF DESCRIPTION OF DRAWINGS

[FIG. 1] is a diagram showing a cabinet of a liquid crystal television according to a first embodiment.

[FIG. 2] is a perspective view showing a part, in which a holder fixing portion is formed in the cabinet, according to the first embodiment.

[FIG. 3] is a perspective view showing the part, in which the holder fixing portion is formed in the cabinet, according to the first embodiment together with a wire holder.

[FIG. 4] are diagrams showing cross-sectional structures of the part, in which the holder fixing portion is formed, according to the first embodiment.

[FIG. 5] are diagrams showing a structure of the holder fixing portion according to the first embodiment by comparing with a conventional structure.

[FIG. 6] are diagrams showing relation between the structure of the holder fixing portion and an inclined core according to the first embodiment by comparing with the conventional structure.

[FIG. 7] are diagrams showing a state where the wire holder is attached to the holder fixing portion according to the first embodiment by comparing with a structure in which a holding rib is not provided.

[FIG. 8] is a perspective view showing a part, in which a holder fixing portion is formed in a cabinet, according to a second embodiment together with a wire holder.

[FIG. 9] are diagrams showing cross-sectional structures of the holder fixing portion before and after the wire holder is attached according to the second embodiment.

[FIG. 10] is a diagram showing relation between the holder fixing portion and an inclined core according to the second embodiment.

[FIG. 11] are diagrams showing a structure of the holder fixing portion according to the second embodiment by comparing with the structure of the first embodiment and the conventional structure.

### DESCRIPTION OF EMBODIMENTS

Next, description will be given specifically for modes for carrying out the present invention (hereinafter, simply referred to as “embodiments”) with reference to drawings.

### First Embodiment

FIG. 1 shows a back surface side of a cabinet 20 of a liquid crystal television 10 according to the present embodiment, and the cabinet 20 which is attached to a front surface side of a display module is shown here. This cabinet is formed by resin molding and fitted and fixed to another cabinet by using, for example, a locking piece for fitting 28 or the like.

Moreover, various harnesses are routed inside of the liquid crystal television 10, and a holder fixing portion 30 therefor is formed in a cabinet back surface 22. FIG. 2 is a perspective view specifically showing a structure of the holder fixing portion 30 by enlarging an area A1 of FIG. 1. In addition, FIG. 3 is a perspective view shown from a different angle, which shows a wire holder 90 together. This wire holder 90 binds harnesses of, for example, a speaker and the like to fix to the cabinet 20. Furthermore, FIG. 4 are diagrams showing cross-sectional structures of the holder fixing portion 30, and FIG. 4(A) is a longitudinal cross-sectional view for showing a state where the wire holder 90 is fixed and FIG. 4(B) is a diagram schematically showing a lateral cross section.

The holder fixing portion 30 is formed in the cabinet back surface 22 at a lower part of the cabinet 20, as shown mainly in FIGS. 1 to 3. More specifically, the holder fixing portion 30 is formed at a step portion 24 of the cabinet back surface 22.

The holder fixing portion 30 is configured by including a box portion 32 and holding ribs 40. The box portion 32 has an open in an upper side in the drawings and is configured by right and left wall surfaces 32a, a rear wall surface 32b and a bottom surface 32c. A holder mounting hole 34 is formed in the rear wall surface 32b, and a wire holder 90 is inserted in a direction of the holder mounting hole 34 (direction of an arrow X1 in the diagrams) to be fixed. In a fixed state, a leaf spring portion 92 (holding portion) of the wire holder 90 is to be placed so as to be in contact with the holding ribs 40.

Moreover, two holding ribs 40 are formed in an extending manner in the bottom surface 32c. End parts in rear sides of the holding ribs 40 are flush with the rear wall surface 32b. In the rear wall surface 32b, restricting walls 36 in the case of fixing the wire holder 90 are formed at two positions in parallel with each other with a predetermined interval. Note that, the number of the holding ribs 40 is not particularly limited, and may be one as long as the leaf spring portion 92 of the wire holder 90 is able to be placed so as to be in contact therewith.

In addition, an inside of the box portion 32 is a so-called undercut portion 50 and is a cavity. That is, due to the undercut portion 50, such a shape is given that a molded article is not able to be taken out in an opening/closing direction of a mold after molding.

Here, description will be given for movement of inclined cores 80 and 180 resulting from the undercut portion 50 of the holder fixing portion 30 with reference to FIG. 4 to FIG. 6. Note that, FIGS. 5 are diagrams showing the structure of the holder fixing portion 30 by comparing with a holder fixing portion 130 of a conventional structure. The holder fixing portion 130 of the conventional structure is only the holder fixing portion 130 and is not provided with the rib 40, as shown in FIG. 5(c). FIGS. 6 show a state where the inclined cores 80 and 180 which form the holder fixing portions 30 and 130 are moved.

As shown in the drawings, it is necessary to relatively move the inclined cores 80 and 180 which are for forming shapes of the holder fixing portions 30 and 130 in an upper direction (direction of an arrow X2) in the drawings once. It is possible to shorten a depth of the undercut portion 50 as shown in the drawings, that is, it is possible to reduce capacity of an inner space. As a result of this, the inclined core 80 of FIG. 6(B) for forming the holder fixing portion 30 of the present embodiment is able to be miniaturized particularly with respect to a moving direction compared to the inclined core 180 of FIG. 6(A), so that a moving range of the inclined core 80 is able to be set small. That is, an area in which shape forming is impossible is able to be made small, and an area in which shape forming is possible is able to be made large.

Here, a holder fixing portion 230 of FIG. 7(A) schematically shows a state where the wire holder 90 is attached to a configuration in which the holding rib 40 is simply removed from the holder fixing portion 30 of the present embodiment. Moreover, FIG. 7(B) shows a state where the wire holder 90 is attached to the holder fixing portion 30.

As shown in FIG. 7(A), in a state where only a shape of a box portion 232 is made small, there is no structure on which one (right side in the diagram) of the leaf spring portion 292 is put, and therefore the wire holder 90 tilts, resulting that desired fixing force does not act. In some cases, there is also a risk that the wire holder 90 comes off the holder mounting hole 34 only with relatively small force acting thereon.

On the other hand, as shown in FIG. 7(B), even when the box portion 32 of the holder fixing portion 30 is made small, the holding rib 40 is provided in the present embodiment. Therefore, the leaf spring portion 92 of the wire holder 90 is in contact with the holding rib 40 in a state where the wire holder 90 is inserted, and force acts on the contact area so as to hold with elastic force.

As above, according to the present embodiment, the holding rib 40 is formed in a side surface of the holder fixing portion 30 in which the holder mounting hole 34 is formed. As a result of this, it is possible to make the undercut portion 50 of the holder fixing portion 30 formed in the cabinet 20 small compared to the conventional structure. By making the undercut portion 50 small, it is possible to reduce a constraint range on the inclined core (mold). That is, the inclined core 80 is able to be miniaturized. On the other hand, since the holding rib 40 is provided, a function of the leaf spring portion 92 of the wire holder 90 is able to be sufficiently exercised, making it possible to prevent the wire holder 90 from being in a tilting state and easily coming off.

### Second Embodiment

Description will be given for a holder fixing portion 330 of a liquid crystal television 310 of the present embodiment with reference to FIG. 8 to FIG. 11. FIG. 8 is a perspective view of the holder fixing portion 330 formed in a cabinet back surface 322 of a cabinet 320. Moreover, FIGS. 9 are cross-sectional views of the holder fixing portion 330 before and after the wire holder 90 is attached. Further, FIG. 10 shows relation between the holder fixing portion 330 and a slide direction of an inclined core 380. Furthermore, FIG. 11 are diagrams schematically showing relation between shapes of the holder fixing portion 330 of the present embodiment (FIG. 11(A)), the holder fixing portion 30 of the first embodiment (FIG. 11(B)) and the holder fixing portion 130 of a conventional technology in a comparable manner.

In the holder fixing portion 330 of the present embodiment, differently from the first embodiment, an orientation of an open of an undercut portion 350, that is, a direction in which the inclined core 380 slides (moves) and a forming direction of holding ribs 340 are different.

Specifically, the holder fixing portion 330 is configured by including a box portion 332 and the holding ribs 340. A space which serves as the undercut portion 350 is formed inside the box portion 332, and a lower side in FIG. 10 serves as the open. That is, as shown in FIG. 8 and FIG. 10, in the undercut portion 350, the open is formed toward an extendingly forming direction of the cabinet 320 (direction of an arrow X3 in the drawings), more specifically, either of right and left directions in the case of an up-and-down frame part and either of up and down directions in the case of a right-and-left frame part.

Further, as holding ribs 340, first and second holding ribs 341 and 342 are formed so as to extend from right and left wall surfaces 332a having the open therebetween. The first and second holding ribs 341 and 342 are formed so as to have the same height as the height of a surface on which the holder mounting hole 34 is formed. When the wire holder 90 is attached, the leaf spring portions 92 are in contact with these first and second holding ribs 341 and 342.

According to the present embodiment, the holding ribs 340 (the first and second holding ribs 341 and 342), which are formed to extend to outer sides in two opposing wall surfaces 332a respectively, are formed. Accordingly, the leaf spring portions 92 are in contact with the first and second holding ribs 341 and 342, so that an attached state of the wire holder 90 is not to be unstable even when the box portion 332 is miniaturized.

As shown in FIGS. 11(A) to (C), it is possible that the holder fixing portion 330 is not only miniaturized more than the holder fixing portion 130 of the conventional technology but miniaturized more than the holder fixing portion 30 of the first embodiment. As a result of this, a degree of freedom in design of the holder fixing portion 330 is improved, thus making it possible to reduce a necessary moving range of the inclined core 380. That is, narrowing of a frame of the cabinet 20 becomes possible.

Note that, as the holding rib 340, only either the first holding rib 341 or the second holding rib 342 may be provided. In this case, because of necessity of securing an area which is in contact with the leaf spring portion 92, it is necessary to enlarge the surface on which the holder mounting hole 334 of the box portion 320 is formed.

As above, description has been given for the present invention based on the embodiments. These embodiments provide exemplifications, and any person with an ordinary skill in the art could understand that, by combining each of the constituent components thereof, various modified examples can be made, and such modified examples are also within the scope of the present invention.

### REFERENCE SIGNS LIST

10 . . . liquid crystal television
20, 320 . . . cabinet
22, 322 . . . cabinet back surface
24 . . . step portion
30, 330 . . . holder fixing portion
32, 332 . . . box portion
32a, 332a . . . side wall surface
32b . . . rear wall surface
32c . . . bottom surface
34, 334 . . . holder mounting hole
40, 340 . . . holding rib
50, 350 . . . undercut portion
341 . . . first holding rib
342 . . . second holding rib

1. A wire holder mounting structure, comprising
a holder fixing portion which is integrally formed on a cabinet and which has a mounting hole by which a wire holder of a snap fixing type is able to be attached and
a rib which is formed so as to extend from the holder fixing portion, wherein
an inner side of a surface, on which the mounting hole is formed, of the holder fixing portion is an undercut portion.

2. A display device having the wire holder mounting structure according to claim 1, wherein,
the wire holder holding a harness is fixed to the wire holder mounting structure as well as a holding portion of the wire holder is in contact with the rib in a fixed state.

3. A wire holder mounting structure, comprising
a holder fixing portion which is integrally formed on a cabinet and which has a mounting hole by which a wire holder of a snap fixing type is able to be attached and
a rib which is formed so as to extend from the holder fixing portion, wherein
an inner side of a surface, on which the mounting hole is formed, of the holder fixing portion is an undercut portion, and
the rib is formed so as to have the same height as the height of a surface on which the mounting hole is formed.

4. A display device having the wire holder mounting structure according to claim 3, wherein,
the wire holder holding a harness is fixed to the wire holder mounting structure as well as a holding portion of the wire holder is in contact with a part, which is the same height as the height of a surface on which the mounting hole is formed, of the rib in a fixed state.
